(19) United States
(12) Patent Application Publication
(10) Pub. No.: US 2017/0279445 A1
(43) Pub. Date: Sep. 28, 2017

(54) AREA-EFFICIENT DIFFERENTIAL SWITCHED CAPACITORS

(71) Applicant: QUALCOMM Incorporated, San Diego, CA (US)

(72) Inventors: Mazhareddin Taghivand, Campbell, CA (US); Alireza Khalili, Sunnyvale, CA (US)

(21) Appl. No.: 15/080,198

(22) Filed: Mar. 24, 2016

(51) Int. Cl. H03K 17/687; H02M 3/07

(52) U.S. Cl. CPC H03K 17/687; H02M 3/07

(57) ABSTRACT

A differential switched capacitor device, including: first and second terminals; first and second branches coupled between the first and second terminals, each branch of the first and the second branches comprising at least one capacitor; and first and second switches, each switch of the first and second switches disposed in each branch of the first and second branches.

### BACKGROUND

### Field

This disclosure relates generally to differential switched capacitors, and more specifically, to area-efficient differential switched capacitors.

### Background

Switched capacitor banks are commonly used for purposes of tuning various radio-frequency (RF) and analog circuit blocks such as voltage-controlled oscillators (VCOs), local oscillator (LO) drivers, low-noise amplifiers (LNAs), mixers (e.g., up/down converters), and power amplifiers (PAs). One of the widely used techniques for implementing a differential capacitor bank 100 may be to configure two capacitors 102, 104 in series with a switch 106 as shown in FIG. 1A. A transistor version 110 in which an n-channel metal oxide semiconductor (NMOS) switch 116 is disposed between the capacitors 112, 114 is shown in FIG. 1B. In this version 110, the size of the NMOS switch 116 may be represented as a ratio of the channel width (W) to the channel length (L), namely ratio W/L.

Another commonly used configuration of a differential capacitor bank 120 is shown in FIG. 1C. This configuration of the differential capacitor bank 120 may include two capacitors 122, 124 with each capacitor 122 or 124 switched with a switch 126 or 128. FIG. 1D is a transistor version 130 including two capacitors 132, 134 and two NMOS switches 136, 138.

For the above illustrated example configuration 110 of FIG. 1B, when the switch 116 is on, the total effective capacitance is the series combination of the two capacitors 112, 114 at the source and drain terminals of the NMOS switch 116. When the switch 116 is off, the total effective capacitance is the series combination of the two capacitors 112, 114 and the drain-to-source off-capacitance (C_{DS}) of the NMOS switch 116. Thus, in one example in which the value of each capacitor 112, 114 is equal to 4C pF, the total effective capacitance of the serial combination of capacitors shown in FIG. 1B is as follows:

$${C}_{eq} = \frac{{C}_{1} {C}_{2}}{{C}_{1} + {C}_{2}} = \frac{( 4 C ) ( 4 C )}{4 C + 4 C} = \frac{16 C}{8 C} = 2 C$$

Thus, in FIG. 1B (or FIG. 1A), to achieve 2C pF of the total effective capacitance when the switch is on, for example, each capacitor must be 4C pF in size. Therefore, in the above example, the total size of the two capacitors must be 8C pF, which may occupy significant area on a chip.

### SUMMARY

The present disclosure describes various implementations of devices and methods for switching area-efficient differential switched capacitors.

In one embodiment, a differential switched capacitor device is disclosed. The device includes: first and second terminals; first and second branches coupled between the first and second terminals, each branch of the first and the second branches comprising at least one capacitor; and first and second switches, each switch of the first and second switches disposed in each branch of the first and second branches.

In another embodiment, a method for switching differential switched capacitors is disclosed. The method includes: switching in a first branch comprising at least one first capacitor between first and second terminals via a first switch; and switching in a second branch comprising at least one second capacitor between the first and the second terminals via a second switch, the second branch in parallel with the first branch.

In yet another embodiment, an apparatus is disclosed. The apparatus includes: means for switching in a first branch comprising at least one first capacitor between first and second terminals; and means for switching in a second branch comprising at least one second capacitor between the first and the second terminals, the second branch in parallel with the first branch.

Other features and advantages of the present disclosure should be apparent from the present description which illustrates, by way of example, aspects of the disclosure.

### BRIEF DESCRIPTION OF THE DRAWINGS

The details of the present disclosure, both as to its structure and operation, may be gleaned in part by study of the appended further drawings, in which like reference numerals refer to like parts, and in which:

FIG. 1A is a schematic diagram of a conventional differential capacitor bank configured with two capacitors in series with a switch;

FIG. 1B is a schematic diagram of a conventional differential capacitor bank configured with two capacitors in series with a transistor switch;

FIG. 1C is a schematic diagram of an alternative implementation of a conventional differential capacitor bank configured with two capacitors and two switches;

FIG. 1D is a schematic diagram of an alternative implementation of a conventional differential capacitor bank configured with two capacitors and two transistor switches;

FIG. 2 is an exemplary wireless device communicating with a wireless communication system;

FIG. 3 is a functional block diagram of an exemplary wireless device in accordance with one embodiment of the present disclosure;

FIG. 4 is a schematic diagram of an exemplary differential capacitor bank in accordance with one embodiment of the present disclosure;

FIG. 5 is a transistor version of the parallel configuration of the switched capacitors configured with two NMOS switches in accordance with one embodiment of the present disclosure; and

FIG. 6 is a detailed schematic diagram of an inverter coupled to the gate terminal of an NMOS switch/transistor in accordance with one embodiment of the present disclosure.

### DETAILED DESCRIPTION

As mentioned above, differential switched capacitor banks are used in various RF and analog circuit blocks such as VCOs, LO drivers, LNAs, mixers (e.g., up/down converters), and PAs included in a wireless device. However, the total size of the capacitors in the switched capacitor banks may occupy significant area on a chip. Thus, in certain implementations, it would be desirable to use differential switched capacitors that are area efficient.

Accordingly, various area efficient switched capacitor banks are proposed for use in various RF and analog circuit blocks. After reading this description it will become apparent how to implement the disclosure in various implementations and applications. Although various implementations of the present disclosure will be described herein, it is understood that these implementations are presented by way of example only, and not limitation. As such, this detailed description of various implementations should not be construed to limit the scope or breadth of the present disclosure.

The term “exemplary” is used herein to mean “serving as an example, instance, or illustration.” Any design described herein as “exemplary” is not necessarily to be construed as preferred or advantageous over other designs. The detailed description includes specific details for the purpose of providing a thorough understanding of the exemplary designs of the present disclosure. It will be apparent to those skilled in the art that the exemplary designs described herein may be practiced without these specific details. In some instances, well-known structures and devices are shown in block diagram form in order to avoid obscuring the novelty of the exemplary designs presented herein.

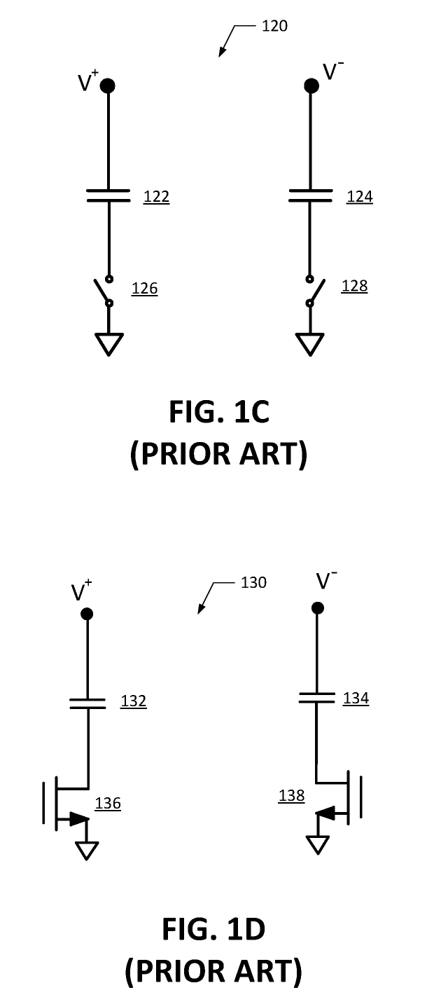

FIG. 2 is an exemplary wireless device 210 communicating with a wireless communication system 200. In one embodiment, the exemplary wireless device 210 includes various RF and analog circuit blocks such as VCOs, LNAs, mixers, and PAs. Wireless communication system 200 may be a Long Term Evolution (LTE) system, a Code Division Multiple Access (CDMA) system, a Global System for Mobile Communications (GSM) system, a wireless local area network (WLAN) system, or some other wireless system. A CDMA system may implement Wideband CDMA (WCDMA), CDMA 1X, Evolution-Data Optimized (EVDO), Time Division Synchronous CDMA (TD-SCDMA), or some other version of CDMA. For simplicity, FIG. 2 shows wireless communication system 200 including two base stations 220 and 222 and one system controller 230. In general, a wireless system may include any number of base stations and any set of network entities.

Wireless device 210 may also be referred to as a user equipment (UE), a mobile station, a terminal, an access terminal, a subscriber unit, a station, etc. Wireless device 210 may be a cellular phone, a smartphone, a tablet, a wireless modem, a personal digital assistant (PDA), a handheld device, a laptop computer, a smartbook, a netbook, a cordless phone, a wireless local loop (WLL) station, a Bluetooth device, etc. Wireless device 210 may communicate with wireless system 200. Wireless device 210 may also receive signals from broadcast stations (e.g., broadcast station 224), signals from satellites (e.g., satellite 240) in one or more global navigation satellite systems (GNSS), etc. Wireless device 210 may support one or more radio technologies for wireless communication including LTE, WCDMA, CDMA 1X, EVDO, TD-SCDMA, GSM, 802.11, etc.

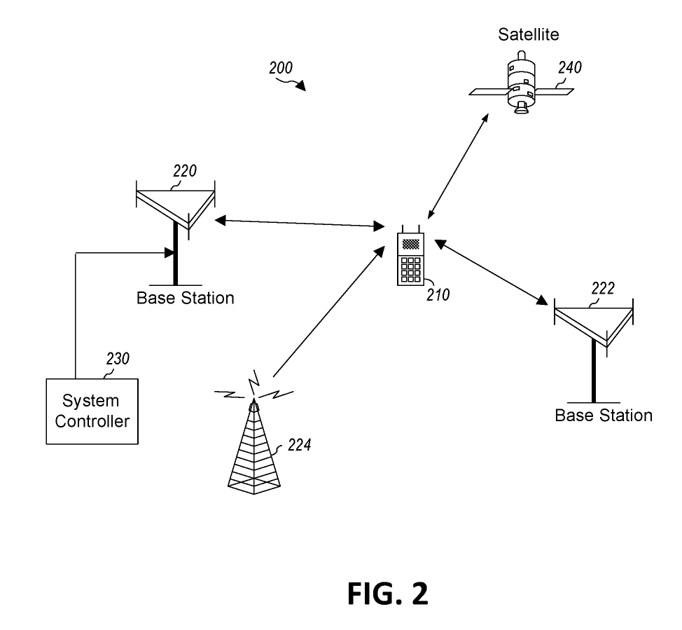

FIG. 3 is a functional block diagram of an exemplary wireless device 300 in accordance with one embodiment of the present disclosure. The wireless device 300 may correspond to the wireless device 210 shown in FIG. 2. The wireless device 300 includes a data processor/controller 310, a transceiver 318, an output device 382, an input device 384, and an antenna 390. The data processor/controller 310 may include memory 312. The transceiver 318 includes a transmitter 320 and a receiver 350 that support bi-directional communication. The transmitter 320 and/or the receiver 350 may be implemented with a super-heterodyne architecture or direct-conversion architecture. In the super-heterodyne architecture, a signal is frequency converted between radio frequency (RF) and baseband in multiple stages, e.g., from RF to an intermediate frequency (IF) in one stage, and then from IF to baseband in another stage for a receiver. In the direct-conversion architecture, which is also referred to as a zero-IF (ZIF) architecture, a signal is frequency converted between RF and baseband in one stage. The super-heterodyne and direct-conversion architectures may use different circuit blocks and/or have different requirements. In the exemplary design shown in FIG. 3, the transmitter 320 and the receiver 350 are implemented with the direct-conversion architecture.

In the transmit path, the data processor/controller 310 may process (e.g., encode and modulate) data to be transmitted and provide the data to a digital-to-analog converter (DAC) 330. The DAC 330 converts a digital input signal to an analog output signal. The analog output signal is provided to a transmit (TX) baseband (lowpass) filter 332, which may filter the analog output signal to remove images caused by the prior digital-to-analog conversion by the DAC 330. An amplifier 334 may amplify the signal from the TX baseband filter 332 and provide an amplified baseband signal. An upconverter (mixer) 336 may receive the amplified baseband signal and a TX local oscillator (LO) signal from a TX LO signal generator 372. The upconverter 336 may upconvert the amplified baseband signal with the TX LO signal and provide an upconverted signal. A filter 338 may filter the upconverted signal to remove images caused by the frequency upconversion. A power amplifier (PA) 340 may amplify the filtered RF signal from the filter 338 to obtain the desired output power level and provide an output RF signal. The output RF signal may be routed through a duplexer/switch 364.

For frequency-division duplexing (FDD), the transmitter 320 and the receiver 350 may be coupled to the duplexer 364, which may include a transmit (TX) filter for the transmitter 320 and a receive (RX) filter for the receiver 350. The TX filter may filter the output RF signal to pass signal components in a transmit band and attenuate signal components in a receive band. For time-division duplexing (TDD), the transmitter 320 and the receiver 350 may be coupled to the switch 364. The switch 364 may pass the output RF signal from the transmitter 320 to the antenna 390 during uplink time intervals. For both FDD and TDD, the duplexer/switch 364 may provide the output RF signal to the antenna 390 for transmission via a wireless channel.

In the receive path, the antenna 390 may receive signals transmitted by base stations and/or other transmitter stations and may provide a received RF signal. The received RF signal may be routed through duplexer/switch 364. For FDD, the RX filter within the duplexer 364 may filter the received RF signal to pass signal components in a receive band and attenuate signal components in the transmit band. For TDD, the switch 364 may pass the received RF signal from the antenna 390 to the receiver 350 during downlink time intervals. For both FDD and TDD, the duplexer/switch 364 may provide the received RF signal to the receiver 350.

Within the receiver 350, the received RF signal may be amplified by a low noise amplifier (LNA) 352 and filtered by a filter 354 to obtain an input RF signal. A downconverter (mixer) 356 may receive the input RF signal and an RX LO signal from an RX LO signal generator 370. The downconverter 356 may downconvert the input RF signal with the RX LO signal and provide a downconverted signal. The downconverted signal may be amplified by an amplifier 358 and further filtered by an RX baseband (lowpass) filter 360 to obtain an analog input signal. The analog input signal is provided to an analog-to-digital converter (ADC) 362. The ADC 362 converts an analog input signal to a digital output signal. The digital output signal is provided to the data processor/controller 310.

The data processor/controller 310 may perform various functions for the wireless device. For example, the data processor/controller 310 may perform processing for data being transmitted via the transmitter 320 and received via the receiver 350. The data processor/controller 310 may control the operation of various circuits within the transmitter 320 and the receiver 350. The memory 312 may store program codes and data for the data processor/controller 310. The memory 312 may be internal or external to the data processor/controller 310. The memory 312 may be referred to as a computer-readable medium. The data processor/controller 310 may be implemented on one or more application specific integrated circuits (ASICs) and/or other ICs.

As mentioned above, differential switched capacitor banks are used in various RF and analog circuit blocks such as VCOs, LNAs, mixers, and PAs included in a wireless device such as the exemplary wireless device 300. However, the total size of the capacitors in the switched capacitor banks may occupy significant area on a chip. Thus, in certain implementations, it would be desirable to use differential switched capacitors that are area efficient

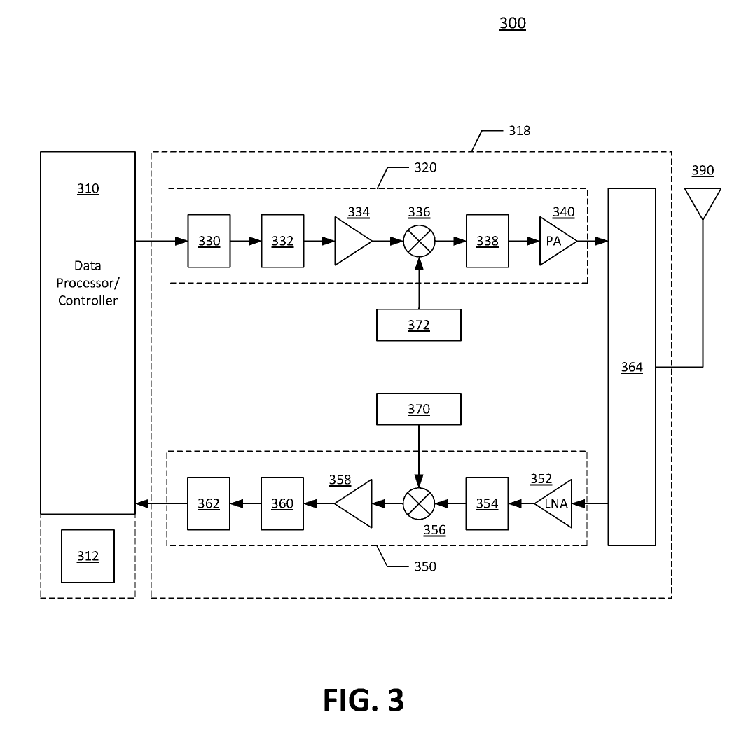

FIG. 4 is a schematic diagram of an exemplary differential capacitor bank 400 in accordance with one embodiment of the present disclosure. In the illustrated embodiment of FIG. 4, to reduce the area occupied by the capacitors 410, 412, the configuration of the differential capacitor bank 400 is modified to be in a parallel configuration. Thus, the parallel configuration splits the capacitors 410, 412 into two branches with each branch including one capacitor 410 or 412 in series with one switch 420 or 422.

In one example in which the value of each capacitor 410, 412 in the configuration shown in FIG. 4 is equal to C pF, the total effective capacitance is as follows:

C_{eq}=C₁+C₂=C+C=2C

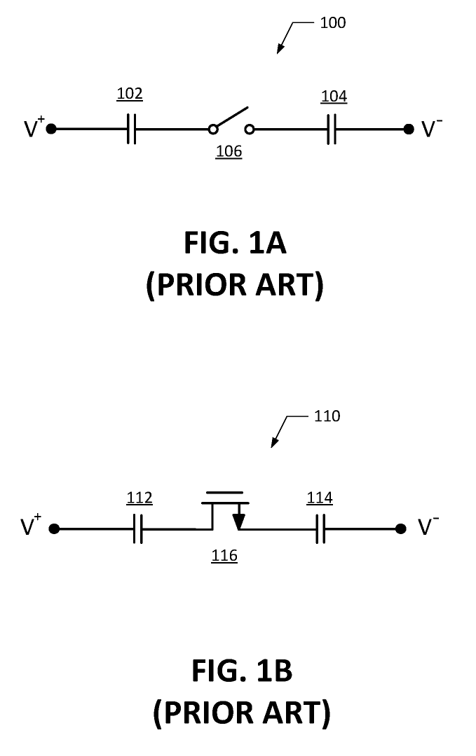

Thus, to achieve 2C pF of the total effective capacitance in the parallel configuration of FIG. 4 (which is same as the serial configuration shown in FIG. 1A or FIG. 1B with each capacitor being 4C pF) when the switch is on, for example, each capacitor must be C pF in size. Therefore, in the above example of FIG. 4, the total size of the two capacitors 410, 412 must be 2C pF, which may be four times less area on a chip than the example shown in FIG. 1A or FIG. 1B (in which the total size of the two capacitors 102/104 or 112/114 is 8C pF). Further, since each switch may be coupled to one capacitor, the size of each switch 420 or 422 in FIG. 4 may be equal to one-half the size of the switch 106 in the example shown in FIG. 1A or the switch 116 in FIG. 1B. Accordingly, the difference in the configuration between the serial configuration of the switched capacitors 102, 104 in FIG. 1A or 112, 114 in FIG. 1B and the parallel configuration of the switched capacitors 410, 412 in FIG. 4 may provide the same total effective capacitance with smaller-sized capacitors and switches in the parallel configuration than the serial configuration.

In the illustrated embodiment of FIG. 4, the differential signal (V⁺/V⁻) is received at terminals 450, 452 and output at the same terminals 450, 452. Terminal 450 receives and outputs the positive differential signal (V⁺) and terminal 452 receives and outputs the negative differential signal (V⁻). The two branches are configured in parallel between the two terminals 450, 452. One branch includes capacitor 410 in series with switch 420, while the other branch includes capacitor 412 in series switch 422. In one embodiment, each of the two branches are switched alternately between the first (e.g., V⁺) and second terminals (e.g., V⁻).

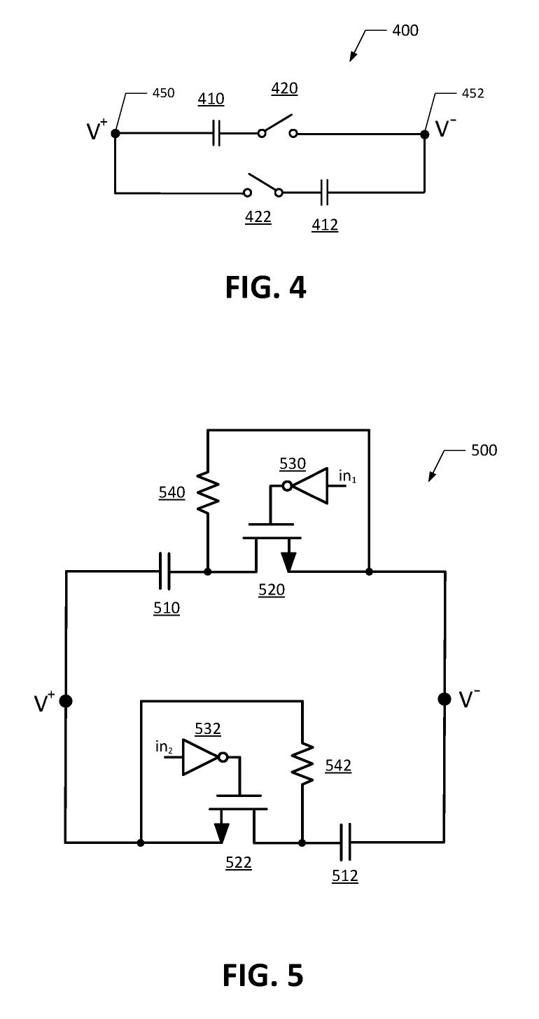

FIG. 5 is a transistor version 500 of the parallel configuration of the switched capacitors configured with two NMOS switches/transistors 520, 522 in accordance with one embodiment of the present disclosure. As explained above, the size of the capacitor in each branch of the parallel configuration may be configured to be one-quarter of the size of each capacitor in the conventional serial configuration shown in FIG. 1A or FIG. 1B, while the size of the switch in each branch of the parallel configuration may be configured to be one-half the size of the switch in the conventional serial configuration shown in FIG. 1A or FIG. 1B.

Thus, in FIG. 1B, the size of each capacitor 112 or 114 is selected to be 4C pF, for example, to achieve the 2C pF total effective capacitance for the serial configuration of FIG. 1B. To achieve the same 2C pF total effective capacitance in the parallel configuration of FIG. 5, the size of each capacitor 510 or 512 is selected to be C pF, which is one-quarter the size of each capacitor in FIG. 1B. Further, the size of the NMOS switch 116 in FIG. 1B, for example, is represented as ratio W/L, while the size of the NMOS switch/transistor 520 or 522 in FIG. 5, for example, is represented as one-half of ratio W/L, namely W/2L.

To further reduce the size of the switch in the parallel configuration, each NMOS switch/transistor 520 or 522 is fabricated, in one embodiment, as a thin oxide transistor of an n-well type transistor. In the n-well type transistor, special regions (called “wells”) are created with a semiconductor type opposite to the substrate type. Thus, in an n-well type NMOS transistor, an n-well is created in a p-type substrate. In another embodiment, each NMOS switch/transistor 520 or 522 is configured as a deep n-well (DNW) type to isolate the NMOS from the substrate of other NMOS transistors.

Further, to keep the voltages from exceeding the DC reliability limit between any two terminals of the transistors, each NMOS switch/transistor 520 or 522 may be configured to be driven with an inverter (or buffer) 530, 532 at the gate terminal of the NMOS switch/transistor 520, 522. Resistors 540, 542 are coupled between drain and source terminals of the NMOS switch/transistors 520, 522, respectively.

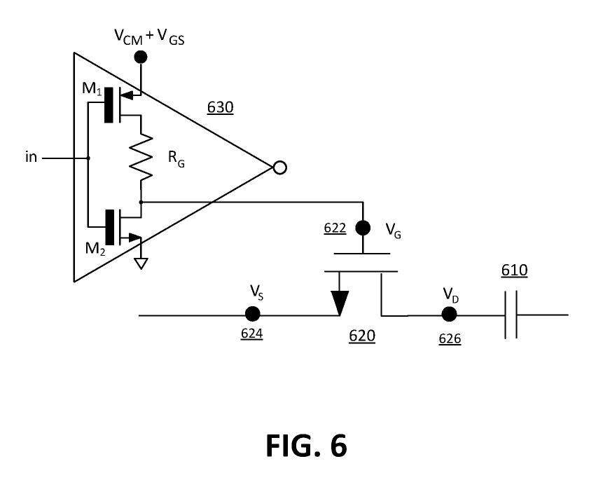

FIG. 6 is a detailed schematic diagram of an inverter 630 coupled to the gate terminal 622 of an NMOS switch/transistor 620 in accordance with one embodiment of the present disclosure. In one embodiment, the inverter 630 may correspond to the inverter 530 shown in FIG. 5, while the NMOS switch/transistor 620 may correspond to the NMOS switch/transistor 520 or 522 shown in FIG. 5. In one embodiment, the NMOS switch/transistor 620 is configured as an n-well thin oxide transistor. In another embodiment, the NMOS switch/transistor 620 is configured as a DNW type transistor.

In the illustrated embodiment of FIG. 6, the NMOS switch/transistor 620 includes gate terminal 622, source terminal 624, and drain terminal 626. Voltage V_{G} represents the voltage at the gate terminal 622, voltage VS represents the voltage at the source terminal 624, and voltage VD represents the voltage at the drain terminal 626. The drain terminal 626 couples to the capacitor 610.

In the illustrated embodiment of FIG. 6, when the input signal (in) of the inverter 630 is high, MOS transistor M1 is turned off, while MOS transistor M2 is turned on to ground the gate terminal 622 of the NMOS transistor 620. When the input signal (in) of the inverter 630 is low, MOS transistor M2 is turned off, while MOS transistor M1 is turned on. The gate terminal 622 of the NMOS transistor 620 now connects to voltage V_{CM}+V_{GS} through resistor R_{G} which is configured to be greater than ten times the impedance of C_{GS}+C_{GD}. Thus, in this configuration, no voltage between two terminals of the thin-oxide NMOS transistor 620 exceeds the DC reliability limit.

Although several embodiments of the disclosure are described above, many variations of the disclosure are possible. For example, although the illustrated embodiments of the present disclosure show the switches/transistor s in an NMOS configuration, other configurations such as a PMOS configuration are possible. Further, features of the various embodiments may be combined in combinations that differ from those described above. Moreover, for clear and brief description, many descriptions of the systems and methods have been simplified. Many descriptions use terminology and structures of specific standards. However, the disclosed systems and methods are more broadly applicable.

Those of skill will appreciate that the various illustrative blocks and modules described in connection with the embodiments disclosed herein can be implemented in various forms. Some blocks and modules have been described above generally in terms of their functionality. How such functionality is implemented depends upon the design constraints imposed on an overall system. Skilled persons can implement the described functionality in varying ways for each particular application, but such implementation decisions should not be interpreted as causing a departure from the scope of the disclosure. In addition, the grouping of functions within a module, block, or step is for ease of description. Specific functions or steps can be moved from one module or block without departing from the disclosure.

The above description of the disclosed embodiments is provided to enable any person skilled in the art to make or use the disclosure. Various modifications to these embodiments will be readily apparent to those skilled in the art, and the generic principles described herein can be applied to other embodiments without departing from the spirit or scope of the disclosure. Thus, it is to be understood that the description and drawings presented herein represent presently preferred embodiments of the disclosure and are therefore representative of the subject matter which is broadly contemplated by the present disclosure. It is further understood that the scope of the present disclosure fully encompasses other embodiments that may become obvious to those skilled in the art and that the scope of the present disclosure is accordingly limited by nothing other than the appended claims.

What is claimed is:

1. A differential switched capacitor device, comprising:
first and second terminals;
first and second branches coupled between the first and second terminals, each branch of the first and the second branches comprising at least one capacitor; and
first and second switches, each switch of the first and second switches disposed in each branch of the first and second branches.

2. The device of claim 1, wherein each of the first and second switches comprises a transistor switch.

3. The device of claim 2, wherein the transistor switch comprises a thin oxide transistor.

4. The device of claim 2, wherein the transistor switch comprises an n-type metal oxide semiconductor (NMOS) transistor.

5. The device of claim 2, wherein the transistor switch comprises an n-well type NMOS transistor.

6. The device of claim 2, wherein the transistor switch comprises a deep n-well (DNW) type NMOS transistor.

7. The device of claim 1, further comprising
first and second inverters coupled to the first and second switches, respectively.

8. The device of claim 1, further comprising:
a first resistor coupled between a source terminal and a drain terminal of the first switch; and
a second resistor coupled between a source terminal and a drain terminal of the second switch.

9. The device of claim 1, wherein the first and second branches are arranged in a parallel configuration.

10. A method for switching differential switched capacitors, the method comprising:
switching in a first branch comprising at least one first capacitor between first and second terminals via a first switch; and
switching in a second branch comprising at least one second capacitor between the first and the second terminals via a second switch, the second branch in parallel with the first branch.

11. The method of claim 10, wherein the first and second branches are switched alternately between the first and second terminals.

12. The method of claim 10, wherein:
the switching in the first branch is based on a first input signal controlling a first switch in the first branch; and
the switching in the second branch is based on a second input signal controlling a second switch in the first branch.

13. The method of claim 12, further comprising inverting at least one of the first and second input signals via an inverter.

14. The method of claim 10, further comprising outputting a first and second output signal from the first and second terminals.

15. The method of claim 14, wherein the first and second output signals are based at least on the switching in the first and second branches.

16. The method of claim 15, wherein the first output signal is an inverted version of the second output signal.

17. The method of claim 10, wherein the first and second switches comprise thin oxide transistor switches.

18. The method of claim 18, wherein the first and second thin oxide transistor switches are n-well type NMOS transistors.

19. The method of claim 17, wherein the first and second thin oxide transistor switches are deep n-well (DNW) type NMOS transistors.

20. An apparatus, comprising:
means for switching in a first branch comprising at least one first capacitor between first and second terminals; and
means for switching in a second branch comprising at least one second capacitor between the first and the second terminals, the second branch in parallel with the first branch.

21. The apparatus of claim 20, wherein the first and second branches are switched alternately between the first and second terminals.

22. The apparatus of claim 20, wherein:
the switching in the first branch is based on a first input signal controlling a first switch in the first branch; and
the switching in the second branch is based on a second input signal controlling a second switch in the first branch.

23. The apparatus of claim 22, further comprising means for inverting at least one of the first and second input signals.

24. The apparatus of claim 20, further comprising means for outputting a first and second output signal from the first and second terminals.

25. The apparatus of claim 24, wherein the first and second output signals are based at least on the switching in the first and second branches.

26. The apparatus of claim 25, wherein the first output signal is an inverted version of the second output signal.

27. The apparatus of claim 20, wherein the first and second means for switching comprise thin oxide transistor switches.

28. The apparatus of claim 27, wherein the first and second thin oxide transistor switches are n-well type NMOS transistors.

29. The apparatus of claim 27, wherein the first and second thin oxide transistor switches are deep n-well (DNW) type NMOS transistors.
